(19) United States
(12) Patent Application Publication
(10) Pub. No.: US 2025/0215569 A1
(43) Pub. Date: Jul. 3, 2025

(54) SHOWER HEAD UNIT, GAS SUPPLY UNIT AND SUBSTRATE PROCESSING DEVICE HAVING THE SAME

(71) Applicant: SEMES CO., LTD., Cheonan-si (KR)

(72) Inventors: Jaeoh BANG, Seoul-si (KR); Seunghwan LEE, Cheonan-si (KR); Gilsoo EUN, Cheonan-si (KR); Sunwoon KIM, Cheonan-si (KR)

(73) Assignee: SEMES CO., LTD., Cheonan-si (KR)

(21) Appl. No.: 18/901,383

(22) Filed: Sep. 30, 2024

(30) Foreign Application Priority Data
Dec. 27, 2023 (KR) 10-2023-0193744

(51) Int. Cl. C23C 16/455; B05B 1/18

(52) U.S. Cl. CPC C23C 16/45565; B05B 1/18

(57) ABSTRACT

A shower head unit configured to uniformly discharge gas for minority wafer surfaces in a photo process, a gas supply unit having the shower head unit and a substrate processing device having the gas supply unit are disclosed. A shower head unit includes a guide member, an inlet member and an injection member. The guide member is disposed to cover a substrate disposed within a process chamber. The inlet member is disposed above the guide member to have a first buffer space therein. The injection member is disposed under the guide member to inject gas supplied from an outside through the first buffer space of the inflow member and the guide member toward the substrate. Therefore, a buffer space is formed in a central portion of the shower head unit so as not to generate eccentricity when gas is injected through the shower head unit, so that uniform injection may be performed through the injection member.

### CROSS-REFERENCE TO RELATED APPLICATIONS

This application claims priority under 35 U.S.C. § 119 to Korean Patent Application No. 10-2023-0193744, filed on Dec. 27, 2023 in the Korean Intellectual Property Office (KIPO), the contents of which are herein incorporated by reference in their entirety.

### BACKGROUND OF THE INVENTION

### Technical Field

Exemplary embodiments of the present invention relate to a shower head unit, a gas supply unit having the shower head unit and a substrate processing device having the gas supply unit. More particularly, exemplary embodiments of the present invention relate to a shower head unit configured to uniformly discharge gas for minority wafer surfaces in a photo process, a gas supply unit having the shower head unit and a substrate processing device having the gas supply unit.

### Discussion of the Related Art

In general, in a photolithography process in a semiconductor device manufacturing process, a hydrophobization treatment is performed to improve the adhesion between a semiconductor wafer (hereinafter referred to as a wafer) and a resist liquid. In the above-described hydrophobization treatment, the surface of the wafer is hydrophobized by supplying hexamethyldisilazane (HMDS) gas to the surface of the wafer disposed in the processing container for a predetermined time. Thereby, it is possible to suppress peeling of the resist film from the surface of the wafer in a subsequent step.

A structure such as making the HMDS gas leaking to the outside of the treatment container lower than or equal to a predetermined concentration is required for the treatment container used for hydrophobic treatment. When the HMDS gas leaks to the outside of the treatment container, it causes particles or produces ammonia that the HMDS gas reacts with moisture in the air to adversely affect the resist.

Meanwhile, the conventional hydrophobic processing apparatus employs an orifice structure, which is a central vertical injection structure. That is, HMDS gas is injected from the center to the nozzle and exhausted from the edge. When the HMDS gas is vertically injected from the center, a problem occurs in that a large deviation between the center and the edge part occurs based on the wafer.

### SUMMARY

Exemplary embodiments of the present invention provide a shower head unit with a buffer space formed therein so that gas for hydrophobizing a wafer surface can be uniformly discharged in a photo process

Exemplary embodiments of the present invention also provide a gas supply unit having the above-mentioned shower head unit.

Exemplary embodiments of the present invention further also provide a substrate processing device having the above-mentioned gas supply unit.

According to one aspect of the present invention, a shower head unit includes a guide member, an inlet member and an injection member. The guide member is disposed to cover a substrate disposed within a process chamber. The inlet member is disposed above the guide member to have a first buffer space therein. The injection member is disposed under the guide member to inject gas supplied from an outside through the first buffer space of the inflow member and the guide member toward the substrate.

In an exemplary embodiment, a central hole may be formed in a central portion of the guide member to move gas, and the central hole may communicate with the first buffer space.

In an exemplary embodiment, a diameter of the first buffer space may be greater than a diameter of the central hole.

In an exemplary embodiment, an exhaust path may be formed in a peripheral area of the guide member for gas exhaustion.

In an exemplary embodiment, a first inflow hole penetrating to the first buffer space to inflow gas may be formed at one side portion of the inflow member.

In an exemplary embodiment, a second buffer space communicating with the first buffer space for gas inflow and a second inlet hole penetrating to the second buffer space may be further formed at the other side portion of the inlet member.

In an exemplary embodiment, the second buffer space may be formed to surround a portion of the first buffer space.

In an exemplary embodiment, an exhaust hole penetrating to the first buffer space for exhausting gas may be formed on the other side portion of the inlet member.

In an exemplary embodiment, the shower head unit may further include a partition wall member disposed in a first buffer space of the inlet member to have a cylindrical shape having a hole formed in an upper region.

In an exemplary embodiment, the partition wall member may have a diameter narrower than a width of the first buffer space.

In an exemplary embodiment, the partition wall member may define a path provided to a hole formed in the guide member by receiving gas flowing along an outer circumferential surface through the hole.

In an exemplary embodiment, a plurality of lower holes of which central axis faces downward for vertical injection of gas may be formed in a lower region of the injection member, and the lower holes may be symmetrically formed.

In an exemplary embodiment, a plurality of inclined holes having a predetermined inclined angle from a reference surface of the substrate may be formed in a side region of the injection member to inject inclined gas, and the inclined holes may be symmetrically formed.

In an exemplary embodiment, the inclined angle may be about 0 degrees to about 15 degrees based on the reference surface.

According to another aspect of the present invention, a gas providing unit includes a gas supply line and a shower head unit. The gas supply line provides a gas flow path to a processing space of a substrate. The shower head unit uniformly provides gas provided through the gas supply line to an entire area of the substrate. The shower head unit includes a guide member, an inlet member and an injection member. The guide member is disposed to cover the substrate. The inlet member is disposed above the guide member to have a first buffer space therein. The injection member is disposed under the guide member to inject gas supplied from an outside through the first buffer space of the inflow member and the guide member toward the substrate.

According to still another aspect of the present invention, a substrate processing device includes a process chamber, a support unit, a heating unit, an exhaust unit and a gas supply unit. The process chamber provides a processing space for heating a substrate. The support unit supports the substrate in the processing space. The heating unit heats the substrate supported by the support unit. The exhaust unit exhausts atmosphere of the processing space. The gas supply unit includes a gas supply line providing a gas flow path to a processing space of a substrate and a shower head unit uniformly providing gas provided through the gas supply line to an entire area of the substrate. The shower head unit includes a guide member, an inlet member and an injection member. The guide member is disposed to cover the substrate. The inlet member is disposed above the guide member to have a first buffer space therein. The injection member is disposed under the guide member to inject gas supplied from an outside through the first buffer space of the inflow member and the guide member toward the substrate.

According to the shower head unit, the gas supply unit having the shower head unit, and the substrate processing device having the gas supply unit, a buffer space is formed in a central portion of the shower head unit so as not to generate eccentricity when gas is injected through the shower head unit, so that uniform injection may be performed through the injection member.

### BRIEF DESCRIPTION OF THE DRAWINGS

The above and other features and aspects of the present invention will become more apparent by describing in detailed exemplary embodiments thereof with reference to the accompanying drawings, in which:

FIG. 1 is a perspective view schematically illustrating a substrate processing device according to one exemplary embodiment of the present invention;

FIG. 2 is a cross-sectional view of the substrate processing device showing a coating block or a developing block shown in FIG. 1;

FIG. 3 is a plan view of the substrate processing device shown in FIG. 1;

FIG. 4 is a cross-sectional view illustrating a substrate processing device according to an exemplary embodiment of the present invention;

FIG. 5 is a rear perspective view illustrating the shower head unit shown in FIG. 4;

FIG. 6 is a cross-sectional view illustrating the shower head unit shown in FIG. 4;

FIG. 7 is a cross-sectional perspective view illustrating an inflow member of the shower head unit shown in FIG. 6;

FIG. 8 is a perspective view illustrating an injection member shown in FIG. 6;

FIG. 9 is a perspective view illustrating another example of the shower head unit shown in FIG. 4;

FIG. 10 is a plan view illustrating the shower head unit shown in FIG. 9;

FIG. 11 is a cross-sectional view illustrating the shower head unit shown in FIG. 10; and

FIG. 12 is a cross-sectional perspective view illustrating another example of the shower head unit shown in FIG. 4.

### DETAILED DESCRIPTION OF THE INVENTION

The present invention is described more fully hereinafter with reference to the accompanying drawings, in which exemplary embodiments of the present invention are shown. The present invention may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-sectional illustrations that are schematic illustrations of idealized exemplary embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

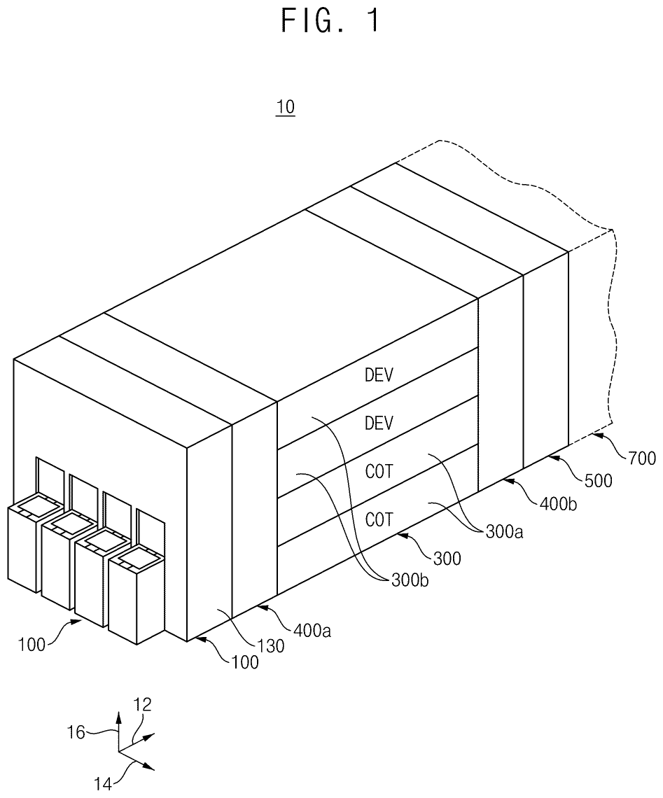

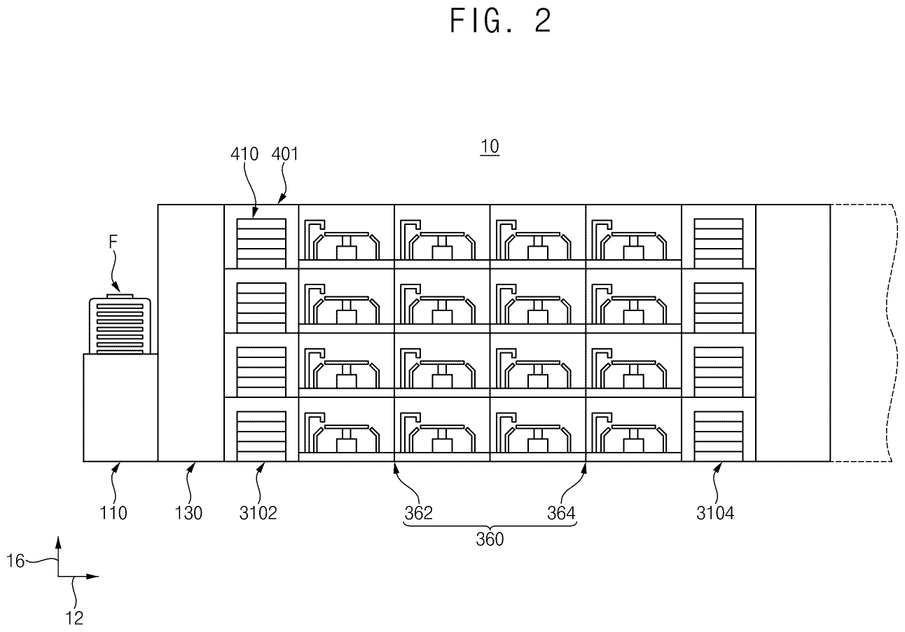

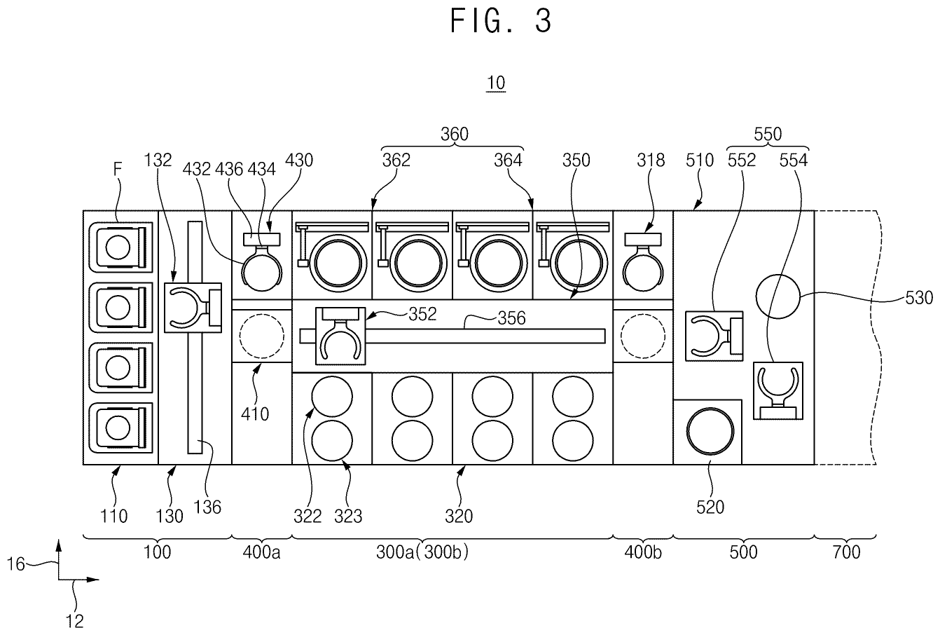

FIG. 1 is a perspective view schematically illustrating a substrate processing device according to an exemplary embodiment of the present invention. FIG. 2 is a cross-sectional view of the substrate processing device showing a coating block or a developing block shown in FIG. 1. FIG. 3 is a plan view of the substrate processing device shown in FIG. 1.

Referring to FIG. 1 through FIG. 3, the substrate processing device 10 according to an exemplary embodiment of the present invention includes an index module 100, a processing module 300, buffer modules 400a and 400b, and an interface module 500. Hereinafter, a direction in which the index module 100, the processing module 300, the buffer modules 400a and 400b, and the interface module 500 are arranged is defines as a first direction 12. A direction perpendicular to the first direction 12 when viewed from the top is defined as a second direction 14. A direction perpendicular to both the first direction 12 and the second direction 14 is defined as a third direction 16.

The index module 100 transfers the substrate W from the container F in which the substrate W is received to the processing module 300, and receives the processed substrate W to the container F. The longitudinal direction of the index module 100 is provided in a second direction 14. The index module 100 includes a load port 110 and an index frame 130. The load port 110 is disposed on the opposite side of the processing module 300 with respect to the index frame 130. The container F in which the substrates W are accommodated is placed in the load port 110. A plurality of load ports 110 may be provided, and a plurality of load ports 110 may be disposed along the second direction 14.

As the container F, a sealing container F such as a front open unified pod (FOUP) may be used. The container F may be placed in the load port 110 by a transfer means (not shown) such as an overhead transfer, an overhead conveyor, or an automatic guided vehicle (AGV), or an operator.

An index robot 132 is provided inside the index frame 130. In the index frame 130, a guide rail 136 having a length direction provided in a second direction 14 may be provided, and the index robot 132 may be provided to be movable on the guide rail 136. The index robot 132 includes a hand on which the substrate W is placed. The hand may be provided to be forward and backward moving, rotating about a third direction 16, and be movable along a third direction 16.

The processing module 300 may perform a coating process and a developing process on the substrate W. The processing module 300 may receive the substrate W accommodated in the container F to perform a substrate processing process. The processing module 300 has a plurality of coating blocks 300a and a plurality of developing blocks 300b. The plurality of coating blocks 300a perform a coating process on the substrate W, and the plurality of developing blocks 300b perform a developing process on the substrate W. The coating blocks 300a are provided to be stacked on each other. The developing blocks 300b are provided to be stacked on each other. According to an exemplary embodiment of FIG. 1, two coating blocks 300a and two developing blocks 300b are provided, respectively. The coating blocks 300a may be disposed under the developing blocks 300b. According to an exemplary embodiment, two coating blocks 300a may perform the same process and may be provided in the same structure. In addition, two developing blocks 300b may perform the same process and may be provided in the same structure.

Referring to FIG. 3, the coating block 300a includes a heat treatment chamber 320, a transfer chamber 350 and a liquid treatment chamber 360. The heat treatment chamber 320 performs a heat treatment process on the substrate W. The heat treatment process may include a cooling process and a heating process. The liquid treatment chamber 360 forms a liquid film by supplying a liquid onto the substrate W. The liquid film may be a photoresist film or an antireflection film. The transfer chamber 350 transfers the substrate W between the heat treatment chamber 320 and the liquid treatment chamber 360 in the coating block 300a.

The transfer chamber 350 is provided with a longitudinal direction parallel to the first direction 12. A transfer robot 352 is provided in the transfer chamber 350. The transfer robot 352 conveys a substrate among the heat treatment chamber 320, the liquid treatment chamber 360 and the buffer module 400. According to an exemplary embodiment, the transfer robot 352 has a hand on which the substrate W is placed. The hand may be provided to be forward and backward moving, rotating about a third direction 16, and movable along a third direction 16. A guide rail 356 having a longitudinal direction parallel to the first direction 12 is provided in the transfer chamber 350, and the transfer robot 352 may be provided to be movable on the guide rail 356.

A plurality of buffer modules 400a and 400b are provided. Some of these buffer modules 400a and 400b are disposed between the index module 100 and the processing module 300. Hereinafter, the buffer modules 400a and 400b are referred to as front end buffers 400a. A plurality of front end buffers 400a is provided, and is positioned to be stacked on each other in the vertical direction. Other buffer modules 400a and 400b are disposed between the processing module 300 and the interface module 500. Hereinafter, these buffer modules 400a and 400b are referred to as rear buffers 400b. A plurality of rear-end buffers 400b are provided, and are positioned to be stacked on each other in the vertical direction. Each of the front end buffers 400a and the rear end buffers 400b temporarily stores a plurality of substrates W. The substrate W stored in the front end buffer 400a is transferred in or out by the index robot 132 and the transfer robot 352. The substrate W stored in the rear buffer is transferred in or out by the transfer robot 352 and the first robot 552.

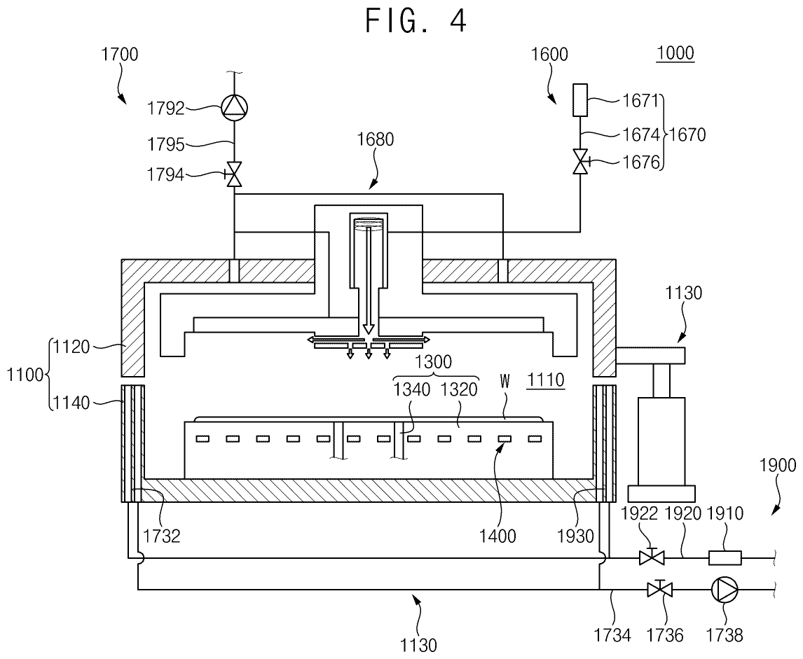

FIG. 4 is a cross-sectional view illustrating a substrate processing device according to an exemplary embodiment of the present invention. The substrate processing device 1000 illustrated in FIG. 4 may be one of the heating units 3230 provided to some of the heat treatment chambers 3200 illustrated in FIG. 1. Referring to FIG. 4, the heating unit 3230 includes a process chamber 1100, a support unit 1300, a heating unit 1400, an exhaust unit 1700, a gas supply unit 1600 and a gas curtain unit 1900.

The process chamber 1100 provides a processing space 1110 for heat-treating the substrate W therein. The processing space 1110 is provided as a space blocked from the outside. The process chamber 1100 includes an upper body 1120 and a lower body 1140. The upper body 1120 is provided in a cylindrical shape with an open lower portion. For example, the upper body 1120 may have a cylindrical shape. An opening is formed in the upper surface of the upper body 1120. The opening may be formed in a region corresponding to the central axis of the upper body 1120. Like the upper body 1120, the lower body 1140 is provided in a cylindrical shape with an open upper portion. For example, the lower body 1140 may have a cylindrical shape. The lower body 1140 is located under the upper body 1120. The upper body 1120 and the lower body 1140 are located to face each other in the vertical direction. The upper body 1120 and the lower body 1140 are combined to form a processing space 1110 therein. The central axes of the upper body 1120 and the lower body 1140 are located to coincide with each other with each other in the vertical direction. The lower body 1140 may have substantially the same diameter as the upper body 1120. That is, the upper end of the lower body 1140 may be positioned to face the lower end of the upper body 1120.

In one example, one of the upper body 1120 and the lower body 1140 may be moved to an open position and a process position by a driver 1130, and the other may be fixed in position. According to an example, the position of the lower body 1140 is fixed, and the upper body 1120 may be moved between the open position and the process position by the driver 1130. Here, the open position is a position where the upper body 1120 and the lower body 1140 are spaced apart from each other to open the processing space 1110. The process position is a position when the substrate is processed in the processing space 1110. In one example, the process position may be a position where the upper body 1120 and the lower body 1140 are spaced apart at a predetermined interval.

For example, the side surfaces between the upper body 1120 and the lower body 1140 in the process position may have an interval of about 1 mm to about 10 mm. In one example, the open position is a position at which the driver 1130 moves the upper body 1120 upward to open the process chamber 1100 when carrying the substrate W into the processing space 1110 or carrying the substrate W out of the processing space 1110. In the present embodiment, the driver 1130 is connected to the upper body 1120, but the driver 1130 may be connected to the lower body 1140 to lift or lower the lower body 1140.

The support unit 1300 supports the substrate W in the processing space 1110. The support unit 1300 is fixed and coupled to the lower body 1140. The support unit 1300 includes a seating plate 1320 and a lift pin 1340. The seating plate 1320 supports the substrate W in the processing space 1110. The seating plate 1320 has a circular plate shape. The substrate W may be seated on an upper surface of the seating plate 1320. A region of the upper surface of the seating plate 1320 including the center thereof functions as a seating surface on which the substrate W is seated. The lift pin 1340 is provided to move in the vertical direction. The lift pin 1340 lifts the substrate W from the seating plate 1320 or mounts the substrate W on the seating plate 1320.

The heating unit 1400 performs a heat treatment process for applying heat to the substrate W placed on the seating plate 1320. The heating unit 1400 is disposed in the seating plate 1320. In one example, the heating unit 1400 may be provided as a plurality of heaters. In one example, a region of the seating plate 1320 corresponding to each heater may be provided as distinguished heating zones. For example, each heater may be provided so that the temperature is independently adjustable. Each heater may be a thermoelectric element or a heating wire.

The exhaust unit 1700 includes a main exhaust line 1795, a pressure reducing member 1792 and an adjustment valve 1794 to exhaust the atmosphere of the processing space 1110. In an example, the exhaust unit 1700 forcibly exhausts an outside air introduced into the processing space 1110. The exhaust unit 1700 is connected to the main exhaust line 1795. A pressure reducing member 1792 and an adjustment valve 1794 are provided in the main exhaust line 1795. The pressure reducing member 1792 provides pressure reducing to the main exhaust line 1795 to exhaust the processing space 1110. The adjustment valve 1794 adjusts pressure of the pressure reducing member 1792 provided to the main line.

The gas supply unit 1600 is disposed above the support unit 1300. The gas supply unit 1600 supplies gas to the processing space 1110. In one example, the gas supply unit 1600 has a gas supply line 1674 and a shower head unit 1680. The gas supply line 1674 supplies gas provided from the gas supply source 1671 to the processing space 1110. Here, the gas is supplied to the processing space during heating of the substrate W to improve the adhesion rate of the photoresist to the substrate W. According to an example, the gas may be hexamethyldisilazane (HMDS) gas. The HMDS gas may change the properties of the substrate W from hydrophilic to hydrophobic. In one example, the HMDS gas may be provided by being mixed with the carrier gas. In one example, the carrier gas may be provided as an inert gas. For example, the inert gas may be nitrogen. A gas control valve 1676 is provided on the gas supply line 1674. The gas control valve 1676 adjusts whether or not gas supplied to the processing space 1110 and the supply flow rate.

In one example, the gas supply line 1674 is disposed at a position corresponding to the central area of the substrate placed on the support unit 1300. In one example, the gas supplied to the processing space is not directly supplied onto the substrate but is supplied via the shower head unit 1680. The shower head unit 1680 performs an operation so that the gas supplied to the processing space may be uniformly provided to an entire area of the substrate.

In one example, the shower head unit 1680 is provided in a size corresponding to the upper surface of the substrate placed on the support unit 1300.

The gas curtain unit 1900 prevents the atmosphere inside the processing space 1110 from flowing out while the substrate W is processing within the processing space 1110. Moreover, the gas curtain unit 1900 prevents outside air from flowing into the processing space 1110 while the substrate W is processing within the processing space 1110. In one example, the gas curtain unit 1900 includes a gas supply line 1920, a supply hole 1930 and a gas supply source 1910. The gas supply line 1920 receives gas from the gas supply source 1910 and supplies the gas to the supply hole 1930. A control valve 1922 is installed in the gas supply line 1920. The control valve 1922 controls whether gas is supplied to the supply hole 1930 and controls the supply flow rate of gas. In an example, the supply hole 1930 injects gas into the space between the upper body 1120 and the lower body 1140 while the substrate W is processed in the processing space 1110. In an example, the gas may include nitrogen.

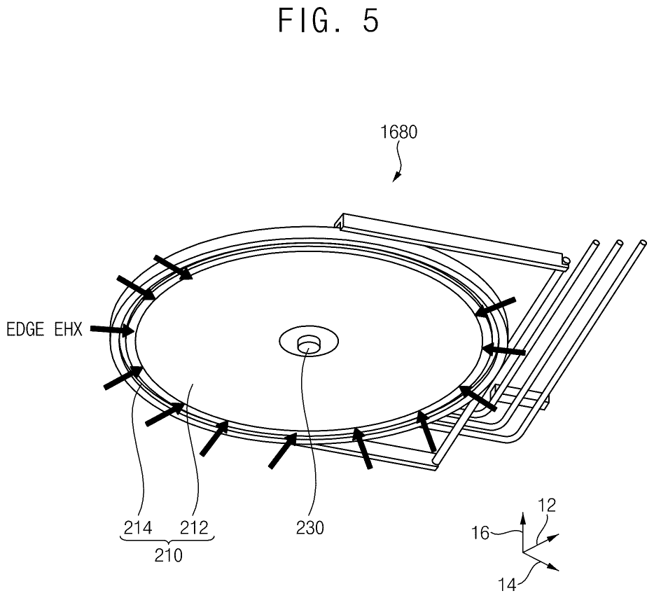

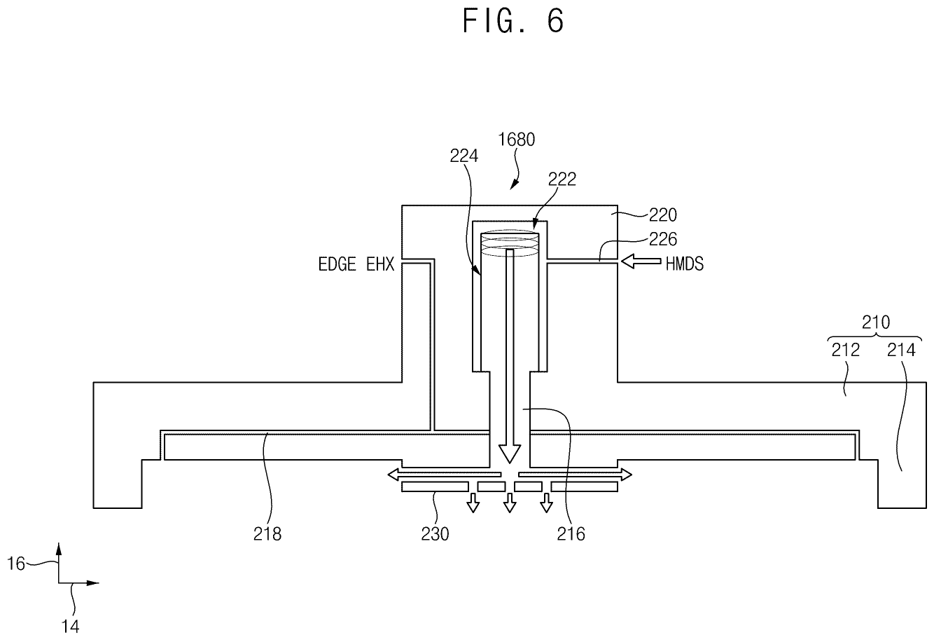

FIG. 5 is a rear perspective view illustrating the shower head unit 1680 shown in FIG. 4. FIG. 6 is a cross-sectional view illustrating the shower head unit 1680 shown in FIG. 4.

Referring to FIG. 4, FIG. 5 and FIG. 6, the shower head unit 1680 includes a guide member 210, an inflow member 220 protruding upward from the guide member 210, and an injection member 230 protruding downward from the guide member 210, and injects gas into the substrate disposed below. In an embodiment, the guide member 210, the inflow member 220, and the injection member 230 may be integrally formed to define the shower head unit 1680. In another embodiment, the guide member 210, the inflow member 220, and the injection member 230 may be separately manufactured and then fastened to define the shower head unit 1680. Here, the gas may be a hydrophobic gas that hydrophobizes the substrate W. According to an embodiment, the hydrophobic gas may be HMDS gas.

The guide member 210 is disposed to cover the substrate. The guide member 210 includes a main body part 212 having a disk shape and an edge part 214 protruding downward from the main body part 212. A central hole 216 is formed in a central portion of the guide member 210 for gas movement. In addition, an exhaust path 218 is formed in a peripheral area of the guide member 210 for gas exhaustion. In this way, since a separate central exhaust path 218 is formed in the guide member 210, a uniform hydrophobic environment with edge exhaust during supersaturation may be formed.

The inflow member 220 is disposed to protrude from an upper portion of the guide member 210, and a first buffer space 222 is formed in the inflow member 220. The first buffer space 222 is communicated with the central hole 216 formed in the guide member 210. The partition member 224 having a diameter substantially narrower than a width of the first buffer space 222 is disposed in the first buffer space 222. The partition member 224 has a cylindrical shape with a hole formed in an upper region. Here, the partition member 224 receives a gas flowing along an outer circumferential surface through a hole formed in an upper region of a cylindrical shape, and provides the gas to the central hole 216 formed in the guide member 210.

The injection member 230 is disposed to protrude from a lower portion of the guide member 210. The injection member 230 injects gas, which is supplied from the outside and passes through the first buffer space 222 of the inflow member 220 and the guide member 210, toward the substrate.

As described above, a first buffer space 222 is formed inside a central portion of the shower head unit 1680 so that eccentricity does not occur when gas is injected through the shower head unit 1680, so that uniform gas injection may be performed through the injection member 230.

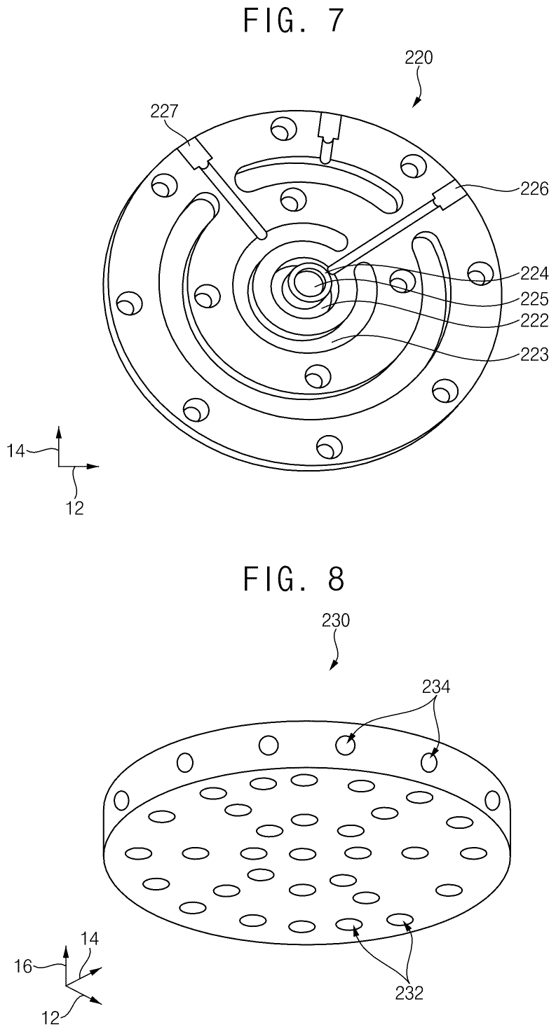

FIG. 7 is a cross-sectional perspective view illustrating an inflow member of the shower head unit shown in FIG. 6. In particular, FIG. 7 is a cross-sectional perspective view extracted from each of upper and lower portions of a region corresponding to the first inflow hole 226 formed in the inflow member 220 shown in FIG. 6.

Referring to FIG. 6 and FIG. 7, a first inflow hole 226 penetrating to the first buffer space 222 for gas inflow is formed in one side region of the inflow member 220. Holes formed in each of the outermost region and the inner region of the outermost region of the inflow member 220 are fastening holes (not shown) for coupling with the guide member 210.

The partition member 224 is disposed in the first buffer space 222 of the inflow member 220 and has a cylindrical shape having a hole formed in an upper region. The partition member 224 may have a diameter narrower than a width of the first buffer space 222.

A second inflow hole 227 penetrating for gas inflow is formed in the other region of the inflow member 220. The second inflow hole 227 penetrates to the second buffer space 223 formed to surround the first buffer space 222. In FIG. 7, the second buffer space 223 is formed to surround a portion of the first buffer space 222. Although not shown, the second buffer space 223 is connected to penetrate the first buffer space 222.

Accordingly, a gas introduced into the second inflow hole 227 reaches the first buffer space 222 via the second buffer space 223. The gas reaching the first buffer space 222 reaches the inside of the partition member 224 through the hole 225 formed in the partition member 224, and then is provided to the injection member 230 through the central hole 216 formed in the guide member 210.

In the present embodiment, it is exemplarily illustrated that the first buffer space 222 and the second buffer space 223 communicating with the first buffer space 222 are formed, and the first inflow hole 226 penetrating to the first buffer space 222 and the second inflow hole 227 penetrating to the second buffer space 223.

In this way, by forming the second inflow hole 227 and the second buffer space 223 separately from the first inflow hole 226 and the first buffer space 222, it is possible to minimize an airflow moment in an internal buffer space.

Although not shown in FIG. 7, a third buffer space (not shown) communicating with the second buffer space 223 may be additionally formed, and a third inflow hole (not shown) penetrating to the third buffer space may be further formed. That is, a plurality of buffer spaces may be formed inside the inflow member 220, and the gas introduced into the buffer spaces may be finally saturated in a central portion of the shower head unit 1680 and sprayed downward.

FIG. 8 is a perspective view illustrating an injection member 230 shown in FIG. 6.

Referring to FIG. 8, the injection member 230 has a disk shape having a predetermined thickness to be communicated with the central hole 216 formed in the guide member 210.

A plurality of lower holes 232 of which the central axis faces downward are formed in a lower region of the injection member 230. Here, the lower holes 232 are formed symmetrically. The gas is vertically injected through the lower holes 232.

In addition, a plurality of inclined holes 234 in which the central axis has an inclined angle from the reference surface of the substrate are formed in the side region of the injection member 230. The gas is injected in an inclined direction through the inclined holes 234. Here, the inclined holes 234 are formed symmetrically. In addition, the inclined angle may have approximately 0° to 15° based on the reference surface of the substrate. In the present embodiment, inclined angles of the inclined holes 234 facing each other may be substantially the same.

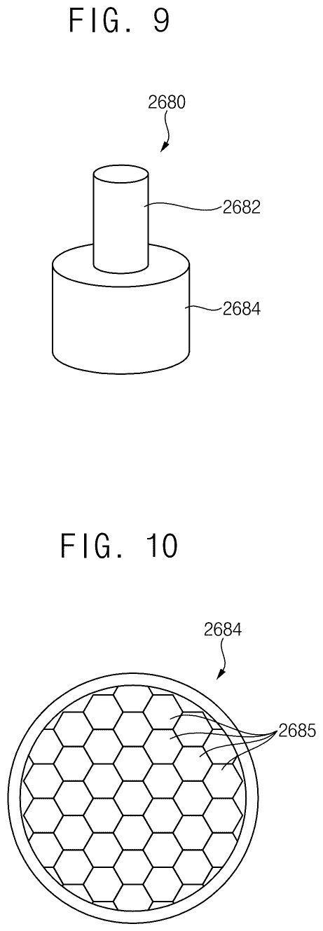

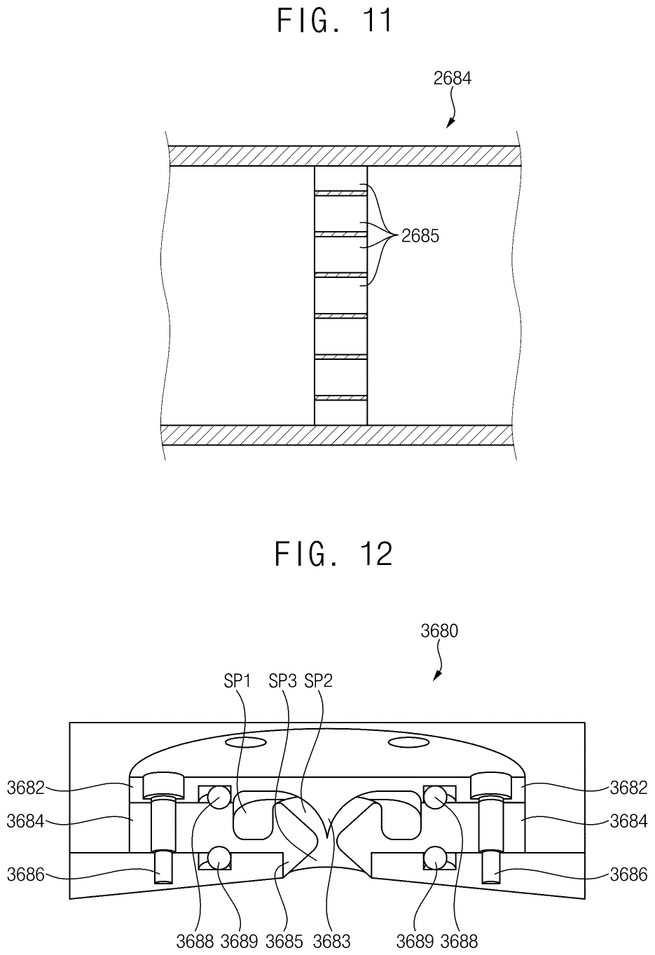

FIG. 9 is a perspective view illustrating another example of the shower head unit shown in FIG. 4. FIG. 10 is a plan view illustrating the shower head unit shown in FIG. 9. FIG. 11 is a cross-sectional view illustrating the shower head unit shown in FIG. 10.

Referring to FIG. 9, FIG. 10 and FIG. 11, the shower head unit 2680 according to another example includes a guide member 2682 formed in a horizontal direction and an orifice member 2684 protruding downward from the guide member 2682, and sprays gas to the substrate disposed below.

The guide member 2682 provides a gas flow path.

The orifice member 2684 is formed to have a plurality of through-holes 2685. The through-holes 2685 pass through the orifice member 2684 in a thickness direction of the orifice member 2684, that is, in a direction in which gas flows from the top to the bottom (in the case of FIG. 9, a direction in which gas flows from the left to the right) (in the case of FIG. 11, a pressure difference occurs before and after the orifice member 2684 through which the gas passes through the through-hole 2685 of the orifice member 2684. Although the through-holes 2685 are shown to have a hexagonal shape when viewed in a plan view, the through-holes 2685 may be formed in various shapes such as a circle, an ellipse, or a polygon when viewed in a plan view.

FIG. 12 is a cross-sectional perspective view illustrating another example of the shower head unit shown in FIG. 4.

Referring to FIG. 12, a shower head unit 3680 according to another example includes an upper body part 3682, a lower body part 3684 and a fastening part 3686.

The upper body part 3682 has a flat cylindrical shape and is fastened to the lower body part 3684 through a fastening part 3686. A first protruding part 3683 that sharply protrudes downward and a first flow path surrounding the first protruding part 3683 are formed in a lower central region of the upper body part 3682.

The lower body part 3684 has a flat cylindrical shape to be fastened to the upper body part 3682 through a fastening part 3686. A second flow path surrounded by having a predetermined gap in the first protruding part 3683 while corresponding to the first flow path formed in the upper body part 3682 is formed in the lower body part 3684. A second protruding part 3685 protruding downward from a central portion thereof is formed in the lower body part 3684. A hole is formed in a central portion of the second protrusion 3685 such that the tip of the first protruding part 3683 is exposed. The diameter of the hole formed in the second protruding part 3685 increases as the distance from the tip of the first protruding part 3683 increases. That is, the hole formed in the second protruding part 3685 has a funnel shape that extends downward.

When the shower head unit is observed in cross section, the second space SP2 defined by the tip portion of the first protruding part 3683 and the second flow path is narrower than the first space SP1 defined by the first flow path and the second flow path. Also, the third space SP3 defined by the shape of the funnel formed in the second protruding part 3685 is wider than the second space SP2. Thus, a pressure difference occurs when the fluid of the first space SP1 passes through the second space SP2 and reaches the third space SP3.

The shower head unit 3680 may further include an upper O-ring 3688 and a lower O-ring 3689. The upper O-ring 3688 is disposed between the upper body part 3682 and the lower body part 3684. The lower O-ring 3689 is disposed between the shower head unit 3680 and the process chamber when the shower head unit 3680 is fastened to a hole formed in the process chamber.

As described above, according to the present invention, a buffer space is formed in a central portion of the shower head unit so as not to generate eccentricity when gas is injected through the shower head unit, so that uniform injection may be performed through the injection member.

Having described exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A shower head unit comprising:
a guide member disposed to cover a substrate disposed within a process chamber;
an inlet member disposed above the guide member to have a first buffer space therein; and
an injection member disposed under the guide member to inject gas supplied from an outside through the first buffer space of the inflow member and the guide member toward the substrate.

2. The shower head unit of claim 1, wherein a central hole is formed in a central portion of the guide member to move gas, and the central hole communicates with the first buffer space.

3. The shower head unit of claim 2, wherein a diameter of the first buffer space is greater than a diameter of the central hole.

4. The shower head unit of claim 1, wherein an exhaust path is formed in a peripheral area of the guide member for gas exhaustion.

5. The shower head unit of claim 1, wherein a first inflow hole penetrating to the first buffer space to inflow gas is formed at one side portion of the inflow member.

6. The shower head unit of claim 5, wherein a second buffer space communicating with the first buffer space for gas inflow and a second inlet hole penetrating to the second buffer space are further formed at the other side portion of the inlet member.

7. The shower head unit of claim 6, wherein the second buffer space is formed to surround a portion of the first buffer space.

8. The shower head unit of claim 1, wherein an exhaust hole penetrating to the first buffer space for exhausting gas is formed on the other side portion of the inlet member.

9. The shower head unit of claim 1, further comprising:
a partition wall member disposed in a first buffer space of the inlet member to have a cylindrical shape having a hole formed in an upper region.

10. The shower head unit of claim 9, wherein the partition wall member has a diameter narrower than a width of the first buffer space.

11. The shower head unit of claim 9, wherein the partition wall member defines a path provided to a hole formed in the guide member by receiving gas flowing along an outer circumferential surface through the hole.

12. The shower head unit of claim 1, wherein a plurality of lower holes of which central axis faces downward for vertical injection of gas are formed in a lower region of the injection member, and the lower holes are symmetrically formed.

13. The shower head unit of claim 1, wherein a plurality of inclined holes having a predetermined inclined angle from a reference surface of the substrate are formed in a side region of the injection member to inject inclined gas, and the inclined holes are symmetrically formed.

14. The shower head unit of claim 13, wherein the inclined angle is about 0 degrees to about 15 degrees based on the reference surface.

15. A gas providing unit comprising:
a gas supply line providing a gas flow path to a processing space of a substrate; and
a shower head unit uniformly providing gas provided through the gas supply line to an entire area of the substrate, wherein the shower head unit comprises:
a guide member disposed to cover the substrate;
an inlet member disposed above the guide member to have a first buffer space therein; and
an injection member disposed under the guide member to inject gas supplied from an outside through the first buffer space of the inflow member and the guide member toward the substrate.

16. The gas providing unit of claim 15, wherein a central hole is formed in a central portion of the guide member to move gas, and the central hole communicates with the first buffer space.

17. The gas providing unit of claim 15, further comprising:
a partition wall member disposed in a first buffer space of the inlet member to have a cylindrical shape having a hole formed in an upper region.

18. A substrate processing device comprising:
a process chamber providing a processing space for heating a substrate;
a support unit supporting the substrate in the processing space;
a heating unit heating the substrate supported by the support unit;
an exhaust unit exhausting atmosphere of the processing space; and
a gas supply unit comprising a gas supply line providing a gas flow path to a processing space of a substrate and a shower head unit uniformly providing gas provided through the gas supply line to an entire area of the substrate, wherein the shower head unit comprises:
a guide member disposed to cover the substrate;
an inlet member disposed above the guide member to have a first buffer space therein; and
an injection member disposed under the guide member to inject gas supplied from an outside through the first buffer space of the inflow member and the guide member toward the substrate.

19. The substrate processing device of claim 18, wherein a central hole is formed in a central portion of the guide member to move gas, and the central hole communicates with the first buffer space.

20. The substrate processing device of claim 18, further comprising:
a partition wall member disposed in a first buffer space of the inlet member to have a cylindrical shape having a hole formed in an upper region.
